(19) United States
(12) Patent Application Publication
(10) Pub. No.: US 2025/0218894 A1
(43) Pub. Date: Jul. 3, 2025

(54) SEMICONDUCTOR MODULE INCLUDING HEAT RADIATION SYSTEM

(71) Applicant: JMJ Korea Co., Ltd., Busan (KR)

(72) Inventor: Yun Hwa CHOI, Busan (KR)

(73) Assignee: JMJ Korea Co., Ltd., Busan (KR)

(21) Appl. No.: 18/662,987

(22) Filed: May 13, 2024

(30) Foreign Application Priority Data
Dec. 29, 2023 (KR) 10-2023-0197593

(51) Int. Cl. H01L 23/46; H01L 23/00

(52) U.S. Cl. CPC H01L 23/46; H01L 24/32; H01L 2224/32225

(57) ABSTRACT

The present invention relates to a semiconductor module including a heat radiation system, and more particularly, to a semiconductor module including a heat radiation system in which heat radiation efficiency of the heat radiation system may be maintained and insulation reliability between semiconductor components and the heat radiation system may be secured.

### CROSS-REFERENCE TO RELATED PATENT APPLICATION

This application claims the benefit of Korean Patent Application No. 10-2023-0197593, filed on Dec. 29, 2023, in the Korean Intellectual Property Office, the disclosure of which is incorporated herein in its entirety by reference.

### BACKGROUND OF THE INVENTION

### 1. Field of the Invention

The present invention relates to a semiconductor module including a heat radiation system, and more particularly, to a semiconductor module including a heat radiation system in which heat radiation efficiency of the heat radiation system may be maintained and insulation reliability between semiconductor components and the heat radiation system may be secured.

### 2. Description of the Related Art

In general, electric and electronic components, in particular, semiconductor components generate excessive heat while being operated so that heat sink may be formed or a cooling system may be applied to prevent overheat and thereby, driving performance may be maintained.

In particular, semiconductor components applied in a high-power application field may efficiently prevent overheat by using a cooling system that circulates a coolant.

For example, compared with an existing silicon power semiconductor, a Wide Band Gap (WBG) power semiconductor device enables improvement in thermal property, fast switching, high voltage/high current properties, and minimization of switching loss and thereby, a system may be downsized and power efficiency may be improved. Accordingly, global power module manufacturers actively produce semiconductor components (power modules) that apply WBG power semiconductor devices.

The semiconductor components to which such WBG power semiconductor devices including SiC power semiconductor devices are applied have the junction temperature of above 175° C. so that the semiconductor components may have a Dual Side Cooling or Double Side Cooling (DSC) structure for efficient heat radiation and may adopt a direct cooling method by using the heat radiation system.

Meanwhile, as illustrated in FIG. 1, when upper and lower bodies 11 and 12 of a heat radiation system (Water Jack) are formed of a metal material as in the past in consideration of thermal conductivity, a terminal 14 of a semiconductor component 13 may penetrate air insulation due to the high density/high electric power semiconductor component 13 and thereby, may be short-circuited with the upper and lower bodies 11 and 12 which are formed of a metal material.

In this regard, there is a demand for the development of a technology that may maintain heat radiation efficiency and secure insulation reliability between semiconductor components and a heat radiation system.

### SUMMARY OF THE INVENTION

The present invention provides a semiconductor module including a heat radiation system in which heat radiation efficiency of the heat radiation system may be maintained and insulation reliability between semiconductor components and the heat radiation system may be secured.

According to an aspect of the present invention, there is provided a semiconductor module including a heat radiation system including: at least one semiconductor component comprising at least one terminal extended toward the outside and electrically connected to other components; a first upper heat radiation component combined to the upper part of the semiconductor component; a first lower heat radiation component combined to the lower part of the semiconductor component to face the first upper heat radiation component; a second upper heat radiation component joined to the upper part of the first upper heat radiation component; and a second lower heat radiation component joined to the lower part of the first lower heat radiation component, wherein a coolant used to cool heat generated from the semiconductor component circulates between the first and second upper heat radiation components or between the first and second lower heat radiation components, the second upper heat radiation component or the second lower heat radiation component includes at least one hole through which a coolant flows in and discharges, and at least any one of the first upper heat radiation component, the first lower heat radiation component, the second upper heat radiation component, and the second lower heat radiation component is formed of a material that is different from each other.

Here, the first upper heat radiation component and the second upper heat radiation component may be formed of each different material or the first lower heat radiation component and the second lower heat radiation component may be formed of each different material.

Also, the first upper heat radiation component and the first lower heat radiation component may be formed of a non-conductive material and the second upper heat radiation component and the second lower heat radiation component may be formed of a conductive material.

Here, the semiconductor component may include an insulating substrate, at least one semiconductor chip installed on the insulating substrate, a molding housing covering the semiconductor chips, and terminals extended toward the outside of the molding housing, wherein the insulating substrate may partially or entirely have a dual side cooling structure which is exposed from the molding housing.

Also, the insulating substrate may contain at least any one of Al₂O₃, AlN, and Si₃N₄.

Also, upper radiation components including the first upper heat radiation component and the second upper heat radiation component and lower radiation components including the first lower heat radiation component and the second lower heat radiation component may be assembled to each other by using assembling parts.

Also, the upper radiation components including the first upper heat radiation component and the second upper heat radiation component and the lower radiation components including the first lower heat radiation component and the second lower heat radiation component may be assembled to each other by through screwing.

Also, the upper radiation components including the first upper heat radiation component and the second upper heat radiation component and the lower radiation components including the first lower heat radiation component and the second lower heat radiation component may be assembled to each other by using an adhesive.

Also, the upper radiation components including the first upper heat radiation component and the second upper heat radiation component and the lower radiation components including the first lower heat radiation component and the second lower heat radiation component may be assembled to each other through laser or ultrasonic welding.

Also, upper joining means may be interposed between the first upper heat radiation component and the upper surface of the semiconductor component and lower joining means may be interposed between the first lower heat radiation component and the lower surface of the semiconductor component.

Here, the upper joining means or the lower joining means may be O-rings which are formed of an elastic material.

Also, the upper joining means or the lower joining means may be paste-form adhesives which are hardened at a predetermined temperature so that the semiconductor component, the first upper heat radiation component, and the first lower heat radiation component may be bonded to each other.

Also, a plurality of radiation fins arranged in a specific pattern may be uprightly formed on at least any one of the upper surface and the lower surface of the semiconductor component.

Also, the first upper heat radiation component or the first lower heat radiation component may be formed of an insulating material.

Also, the flow velocity of a coolant which flows through a first flow path formed between the first upper heat radiation component and the second upper heat radiation component or a second flow path formed between the first lower heat radiation component and the second lower heat radiation component may be 5 L/m through 20 L/m.

Also, the semiconductor chip may be a semiconductor including at least any one of GaN, SiC, and Ga₂O₃.

Also, the weight of the first upper heat radiation component or the first lower heat radiation component may be less than the weight of the second upper heat radiation component or the second lower heat radiation component.

Also, the semiconductor component may be grouped into 3 for driving a three phase motor.

Also, first concave parts may be formed on the upper part of the first upper heat radiation component and first convex parts corresponding to the first concave parts may be formed on the lower part of the second upper heat radiation component so as to be joined to each other, and second concave parts may be formed on the lower part of the first lower heat radiation component and second convex parts corresponding to the second concave parts may be formed on the upper part of the second lower heat radiation component so as to be joined to each other.

Also, the first concave parts may be formed on the upper part of the first upper heat radiation component, first O-rings may be entered into the first concave parts, the second concave may be formed on the lower part of the first lower heat radiation component, and second O-rings are entered into the second concave parts.

Also, the first concave parts may be formed on the upper part of the first upper heat radiation component, first adhesives may be filled in the first concave parts, the second concave may be formed on the lower part of the first lower heat radiation component, and second adhesives may be filled in the second concave parts.

Also, first hooks may be formed along the upper edge of the first upper heat radiation component, first hook holes corresponding to the first hooks may be formed on the lower part of the second upper heat radiation component, second hooks may be formed along the lower edge of the first lower heat radiation component, and second hook holes corresponding to the second hooks may be formed on the upper part of the second lower heat radiation component.

Here, the size of the first hook holes and second hook holes may be respectively larger than the size of the first hooks and second hooks and O-rings may be each buried and installed to the first hook holes and the second hook holes.

Here, a connection structure of the first hook holes and the first hooks and a connection structure of the second hook holes and the second hooks may be a cylindrical form, a hexahedral form, or an interlocked structure having a specific form.

Also, the first upper heat radiation component and the first lower heat radiation component may face and cover the semiconductor component, the second upper heat radiation component may cover the first upper heat radiation component, and the second lower heat radiation component may cover the first lower heat radiation component.

Here, the first upper heat radiation component and the first lower heat radiation component may be each separated and disposed on both openings where the terminals extended toward the outside of the molding housing of the semiconductor component are formed.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a semiconductor module including a heat radiation system according to a prior art;

FIG. 2 illustrates a semiconductor module including a heat radiation system according to a first embodiment of the present invention;

FIG. 3 is a cross-sectional view of the semiconductor module including a heat radiation system of FIG. 2;

FIGS. 4 and 5 are exploded views respectively illustrating an example of the semiconductor module including a heat radiation system of FIG. 2;

FIG. 6 is an exploded view illustrating another example of the semiconductor module including a heat radiation system of FIG. 2;

FIGS. 7A and 7B are cross-sectional views schematically illustrating the semiconductor module including a heat radiation system of FIG. 2;

FIG. 8 is a front view of a semiconductor module including a heat radiation system according to a second embodiment of the present invention; and

FIG. 9 illustrates the semiconductor module including a heat radiation system of FIG. 8 where an upper cover and a lower cover are separated from each other.

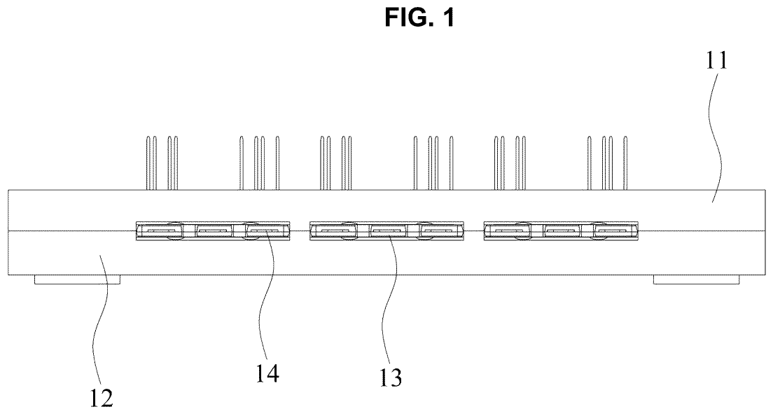

### DETAILED DESCRIPTION OF THE INVENTION

Hereinafter, embodiments of the present invention will be described in more detail with reference to the accompanying drawings.

A semiconductor module including a heat radiation system according to an embodiment of the present invention includes at least one semiconductor component 110 including at least one terminal 117 extended toward the outside and electrically connected to other components, a first upper heat radiation component 120 combined to the upper part of the semiconductor components 110, a first lower heat radiation component 130 combined to the lower part of the semiconductor component 110 to face the first upper heat radiation component 120, a second upper heat radiation component 140 joined to the upper part of the first upper heat radiation component 120, and a second lower heat radiation component 150 joined to the lower part of the first lower heat radiation component 130. Here, a coolant used to cool heat generated from the semiconductor component 110 circulates between the first and second upper heat radiation components 120 and 140 and/or between the first and second lower heat radiation components 130 and 150. Also, the second upper heat radiation component 140 and/or the second lower heat radiation component 150 may include at least one hole through which a coolant flows in and discharges, and at least any one of the first upper heat radiation component 120, the first lower heat radiation component 130, the second upper heat radiation component 140, and the second lower heat radiation component 150 may be formed of a material that is different from each other. Accordingly, heat radiation efficiency of the heat radiation system may be maintained and insulation reliability between the semiconductor component 110 and the heat radiation system may be secured.

Here, the first upper heat radiation component 120 and the second upper heat radiation component 140 may be formed of each different material or the first lower heat radiation component 130 and the second lower heat radiation component 150 may be formed of each different material.

For example, except for the first upper heat radiation component 120, the second upper heat radiation component 140, the first lower heat radiation component 130, and the second lower heat radiation component 150 may be formed of the same material or except for the first lower heat radiation component 130, the first upper heat radiation component 120, the second upper heat radiation component 140, and the second lower heat radiation component 150 may be formed of the same material.

However, the present invention is not limited thereto and the first upper heat radiation component 120, the second upper heat radiation component 140, the first lower heat radiation component 130, and the second lower heat radiation component 150 may be formed of each different material having various combinations. This is because the heat radiation system according to an embodiment of the present invention below adopts a dual side cooling (DSC) structure and a direct cooling method which may bring excellent heat radiation efficiency compared with that of in the past and thereby, freedom of choice for materials may be improved.

Particularly, in the semiconductor module including a heat radiation system according to an embodiment of the present invention, the first upper heat radiation component 120 and the first lower heat radiation component 130 may be formed of a non-conductive material and the second upper heat radiation component 140 and the second lower heat radiation component 150 may be formed of a conductive material.

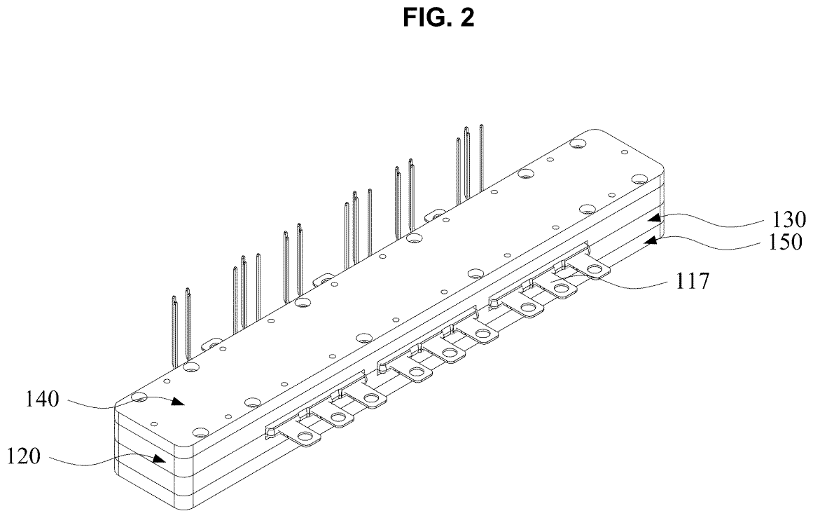

Hereinafter, the semiconductor module including a heat radiation system above will be described in more detail with reference to FIGS. 2 through 9.

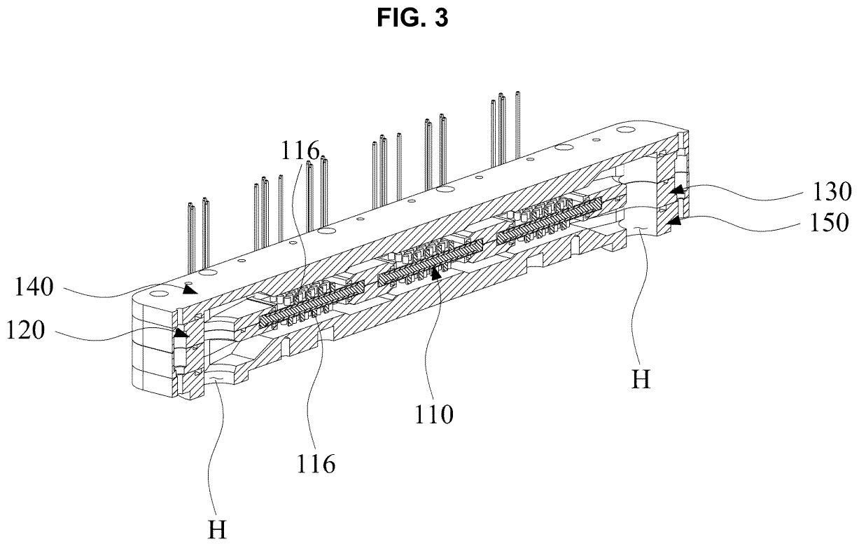

First, referring to FIGS. 3 through 6, at least one semiconductor component 110 is interposed between the first upper heat radiation component 120 and the first lower heat radiation component 130.

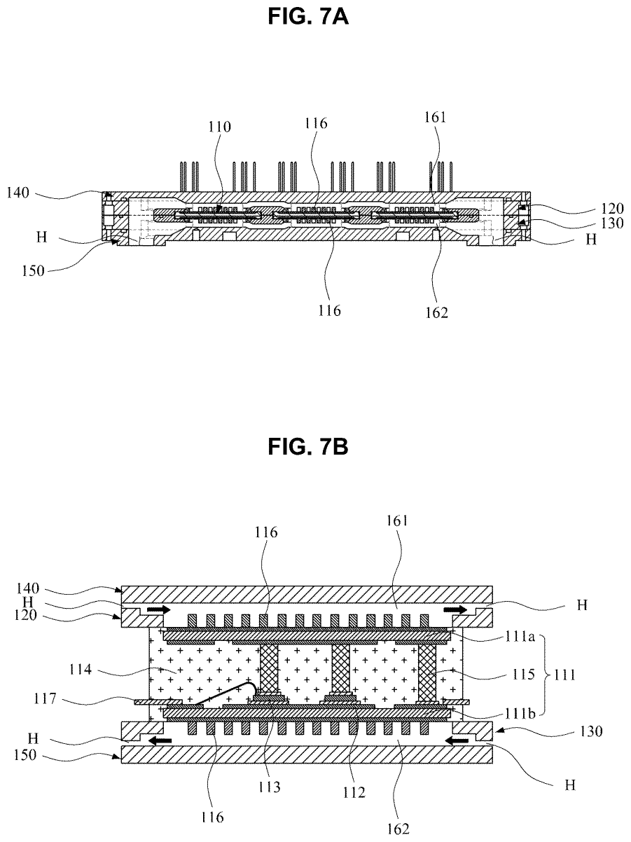

More specifically, the semiconductor component 110 includes an insulating substrate 111, at least one semiconductor chips 113 installed on the insulating substrate 111 by using adhesives 112, a molding housing 114 covering the semiconductor chip 113, and the terminals 117 extended toward the outside of the molding housing 114, as illustrated in FIGS. 7A and 7B. Here, the insulating substrate 111 may partially or entirely have a DSC structure and a direct cooling structure which is exposed from the molding housing 114 (a structure in which at least a part of the insulating substrate is exposed from the molding housing and directly contacts a coolant so as to radiate heat) and thus, heat radiation efficiency may be increased.

Also, the semiconductor component 110 may be grouped into 3 for driving a three phase motor.

Here, the insulating substrate 111 includes an upper substrate 111a and a lower substrate 111b, wherein a spacer 115 may be interposed between the upper substrate 111a and the lower substrate 111b and the semiconductor chips 113 may be installed on the upper substrate 111a, the lower substrate 111b, or both upper substrate 111a and the lower substrate 111b.

Also, the spacer 115 may be a metal post or a clip structure.

In addition, the insulating substrate 111 may contain at least any one of Al₂O₃, AlN, and Si₃N₄.

Moreover, referring to FIGS. 7A and 7B, the upper substrate 111a and/or the lower substrate 111b may have a structure where at least one lower metal layer, an insulating layer, and at least one upper metal layer are stacked in order.

Furthermore, the semiconductor chip 113 may be a compound semiconductor including at least any one of GaN, SiC, and Ga₂O₃, for example, a power conversion semiconductor chip. As illustrated above, the semiconductor component 110 may be a device such as an inverter, a converter, or an on board charger (OBC) that drives a three phase motor or coverts or control power. Here, excessive heat is generated while power is converted into another power having a specific current, a specific voltage, or specific frequency and thereby, cooling may be performed by using the heat radiation system according to an embodiment of the present invention.

Meanwhile, the heat radiation system according to an embodiment of the present invention may include a coolant that circulates a flow path formed between the first upper heat radiation component 120 and the second upper heat radiation component 140, the first lower heat radiation component 130 and the second lower heat radiation component 150, and/or the first upper heat radiation component 120 and the first lower heat radiation component 130. However, the present invention is not particularly restricted and the heat radiation system may be formed to have four or more stages.

That is, referring to FIGS. 2 through 6, the first upper heat radiation component 120 is combined to the upper part of the semiconductor component 110 and the first lower heat radiation component 130 is combined to the lower part of the semiconductor component 110 to face the first upper heat radiation component 120. Accordingly, heat generated from the semiconductor component 110 may be radiated by conduction.

Here, the first upper heat radiation component 120 and the first lower heat radiation component 130 are formed of a non-conductive material and thereby, an insulation distance between the first upper and lower heat radiation components 120 and 130 and the terminals 117 of the high density and high power semiconductor component 110 may be secured. Accordingly, the first upper heat radiation component 120 and the first lower heat radiation component 130 may be blocked from an unexpected short-circuit with the terminals 117 of the semiconductor component 110, wherein the short-circuit may occur if the first upper and lower heat radiation components 120 and 130 are formed of a conductive metal material as in the past. Therefore, electrical reliability between the semiconductor component 110 and the heat radiation system may be secured.

Also, the first upper heat radiation component 120 and the first lower heat radiation component 130 are formed of an insulation material and thereby, may keep an insulation distance from the semiconductor component 110 by more than a fixed separation distance. Accordingly, insulation may be secured.

Here, the first upper heat radiation component 120 and the first lower heat radiation component 130 may be formed of a high heat-resistant resin which is non-conductive and withstands 200° C. or above.

Next, referring to FIGS. 2 through 6, the second upper heat radiation component 140 is joined to the upper part of the first upper heat radiation component 120 and the second lower heat radiation component 150 is joined to the lower part of the first lower heat radiation component 130.

Referring to FIGS. 3, 7A and 7B, according to the structure of the heat radiation system described above, a coolant used to cool heat generated from the semiconductor component 110 may flow between the first upper heat radiation component 120 and the second upper heat radiation component 140 and/or between the first lower heat radiation component 130 and the second lower heat radiation component 150 and at least one hole H through which a coolant flows in and discharges may be formed in the second upper heat radiation component 140 and/or the second lower heat radiation component 150.

Also, a coolant flows through a first flow path 161 formed between the first upper heat radiation component 120 and the second upper heat radiation component 140 and/or a second flow path 162 formed between the first lower heat radiation component 130 and the second lower heat radiation component 150 and the flow velocity thereof may be 5 L/m through 20 L/m. If the flow velocity of a coolant is below 5 L/m, cooling efficiency may be lowered due to residual heat generated by relatively slow flow velocity and if the flow velocity of a coolant exceeds 20 L/m, heat absorption efficiency is lowered due to relatively fast flow velocity and consequentially, cooling efficiency may be lowered. In this regard, the flow velocity of a coolant may be preferably 5 L/m through 20 L/m

In addition, referring to FIGS. 3 through 7B, a plurality of radiation fins 116 arranged in a specific pattern is uprightly formed on the upper surface, the lower surface, or both upper and lower surfaces of the semiconductor component 110 and is structurally exposed to expand a contact area with a coolant. Accordingly, heat radiation efficiency may be increased and cooling efficiency may be maximized due to a direct cooling method by the radiation fins 116. In this regard, a material forming the first upper heat radiation component 120 and the first lower heat radiation component 130 which cover the semiconductor component 110 may not be always a conductive material so that a material for forming heat radiation components may be chosen from a wide range of options and thereby, various materials may be applied.

Moreover, the second upper heat radiation component 140 and the second lower heat radiation component 150 may be formed of a conductive material so that heat conducted from the semiconductor component 110 contacts outside air and thereby, heat radiation efficiency may be increased.

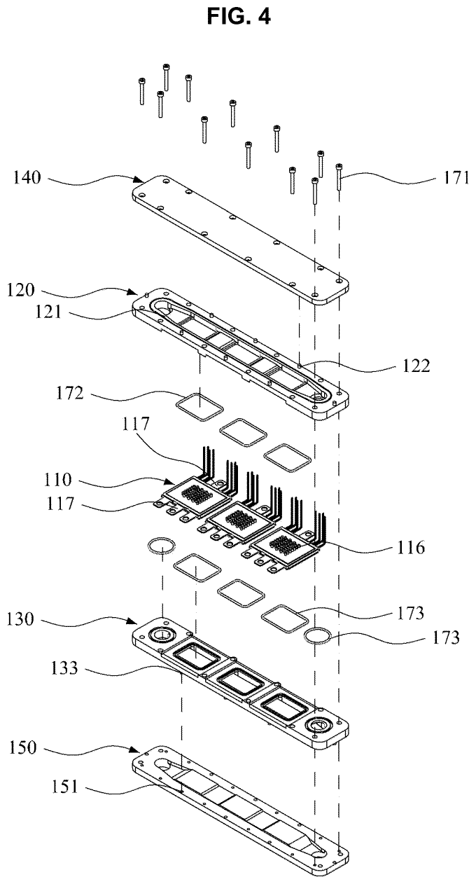

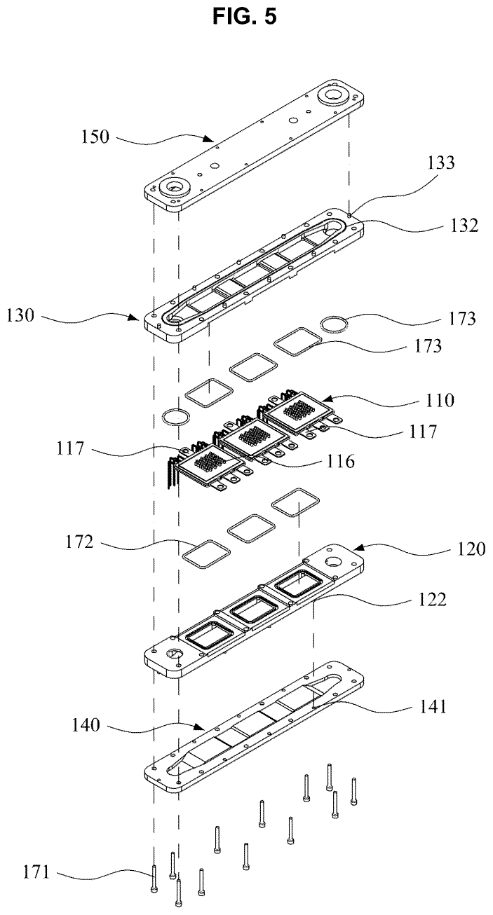

FIGS. 4 and 5 are exploded views respectively illustrating an example of the semiconductor module including a heat radiation system of FIG. 2. Referring to FIGS. 4 and 5, upper radiation components including the first upper heat radiation component 120 and the second upper heat radiation component 140 and lower radiation components including the first lower heat radiation component 130 and the second lower heat radiation component 150 may be assembled and fixed to each other through assembling parts 171 such as bolts.

More specifically, the upper radiation components including the first upper heat radiation component 120 and the second upper heat radiation component 140 and the lower radiation components including the first lower heat radiation component 130 and the second lower heat radiation component 150 may be assembled to each other by screwing, an adhesive, or laser or ultrasonic welding.

Also, upper joining means 172 may be interposed between the first upper heat radiation component 120 and the upper surface of the semiconductor component 110 and lower joining means 173 may be interposed between the first lower heat radiation component 130 and the lower surface of the semiconductor component 110. Here, the upper joining means 172 or the lower joining means 173 may be O-rings which are formed of an elastic material and may increase water tightness between the semiconductor component 110 and the heat radiation system according to a direct cooling method.

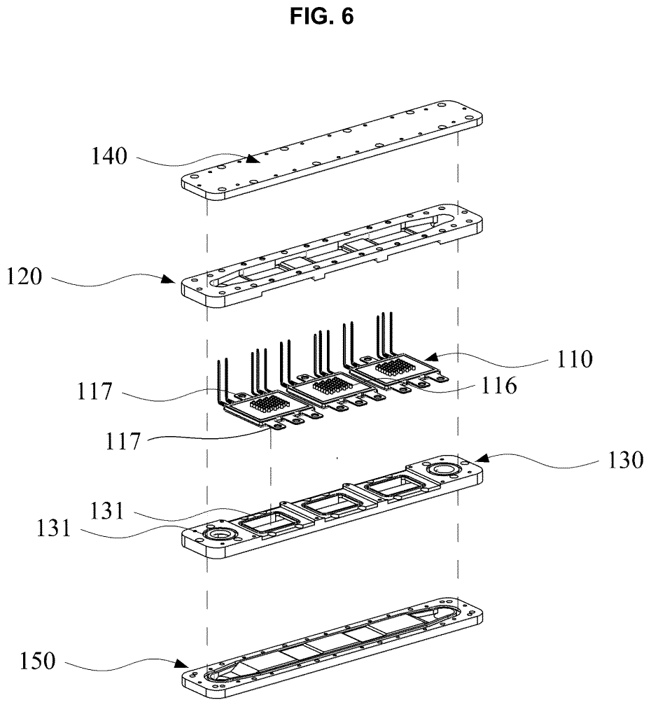

FIG. 6 is an exploded view illustrating another example of the semiconductor module including a heat radiation system of FIG. 2. Here, the upper joining means 172 or the lower joining means 173 may be paste-form adhesives, wherein the adhesives are filled in grooves (not illustrated) formed on the lower surface of the first upper heat radiation component 120 which faces the semiconductor component 110 or grooves 131 formed on the upper surface of the first lower heat radiation component 130 which faces the semiconductor component 110 so that the first upper heat radiation component 120 and the first lower heat radiation component 130 may be bonded to each other and water tightened and thereby, the adhesives may be prevented from being spread.

That is, the paste-form adhesives are filled in the grooves 131 and are hardened at a predetermined temperature, for example, 15° C. or above, preferably, 15° C. through 150° C., by using an oven. Accordingly, the semiconductor component 110, the first upper heat radiation component 120, and the first lower heat radiation component 130 may be bonded to each other.

Therefore, unlike an example described above, the semiconductor component 110, the first upper heat radiation component 120, and the first lower heat radiation component 130 may be water tightened without O-rings, the hardening time may be shortened by using an oven, and bonding may be available at a room temperature within 24 hours.

Meanwhile, the O-rings described in an example and the paste-form adhesives described in another example may be used in a mixed form. That is, the adhesives may be used to bond and water tighten the semiconductor component 110, the first upper heat radiation component 120, and the first lower heat radiation component 130, the O-rings may be used to water tighten the semiconductor component 110, the first upper heat radiation component 120, and the first lower heat radiation component 130, or bolts may be used to assemble the first and second upper heat radiation components 120 and 140 and the first and second lower heat radiation components 130 and 150.

Also, referring to FIGS. 4 and 5, concave parts 121 are formed on the upper part of the first upper heat radiation component 120 and convex parts (not illustrated) corresponding to the concave parts 121 are formed on the lower part of the second upper heat radiation component 140. Accordingly, the concave parts 121 and the convex parts may be joined to each other to increase water tightness, O-rings (not illustrated) may be entered into the concave parts 121 to additionally increase water tightness, or paste-form adhesives may be filled in the concave parts 121 to bond the first upper heat radiation component 120 to the second upper heat radiation component 140 so as to increase water tightness and to prevent the adhesives from being spread.

Such combination of the concave parts 121 and the convex parts is applied between groove parts 132 of the first lower heat radiation component 130 and convex parts (not illustrated) of the second lower heat radiation component 150 as in the same manner so that water tightness may be increased or the adhesives may be prevented from being spread.

In addition, hooks 122 are formed along the upper edge of the first upper heat radiation component 120 and hook holes 141 corresponding to the hooks 122 are formed on the lower part of the second upper heat radiation component 140 so that the hooks 122 and the hook holes 141 are aligned and connected to each other. Moreover, hooks 133 are formed along the lower edge of the first lower heat radiation component 130 and hook holes 151 corresponding to the hooks 133 are formed on the upper part of the second lower heat radiation component 150 so that the hooks 133 and the hook holes 151 are aligned and connected to each other so as to increase water tightness.

Here, locations where the hooks 122 and 133 and the hook holes 141 and 151 are formed may be switched and a connection structure of the hooks 122 and 133 and the hook holes 141 and 151 may be a cylindrical form. However, the present invention is not limited thereto and the connection structure thereof may be a hexahedral form, that is, the connection structure of the hook holes in a hexahedral form having a hollow therein and the hooks in a hexagonal column, or an interlocked structure of a ‘ [symbol] ’ letter form and a ‘ [symbol] ’ letter form.

Also, the size of the hook holes 141 and 151 may be relatively larger than the size of the hooks 122 and 133 and additional O-rings are installed to the hook holes 141 and 151. Then, the hooks 122 and 133 may be connected to the hook holes 141 and 151 and thereby, water tightness may be further secured.

In addition, the weight of the first upper heat radiation component 120 or the first lower heat radiation component 130 may be less than the weight of the second upper heat radiation component 140 or the second lower heat radiation component 150 so that the total weight of the heat radiation system may be reduced.

More specifically, the weight of the first upper heat radiation component 120 may be less than the weight of the second upper heat radiation component 140, the weight of the first lower heat radiation component 130 may be less than the weight of the second lower heat radiation component 150, and the total weight of the first upper heat radiation component 120 and the first lower heat radiation component 130 may be less than the total weight of the second upper heat radiation component 140 and the second lower heat radiation component 150.

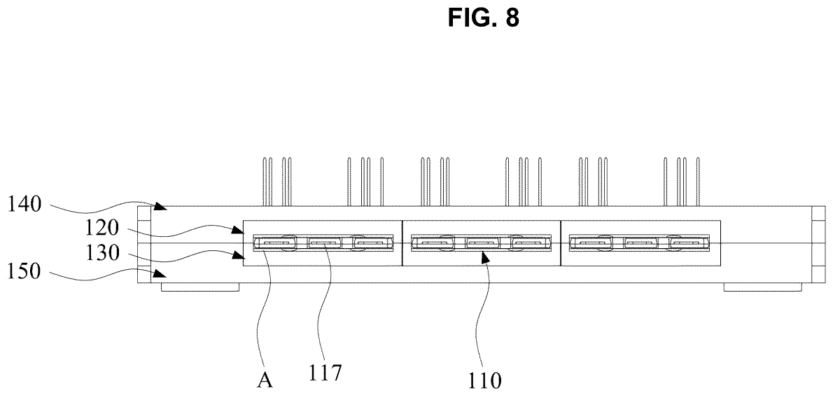

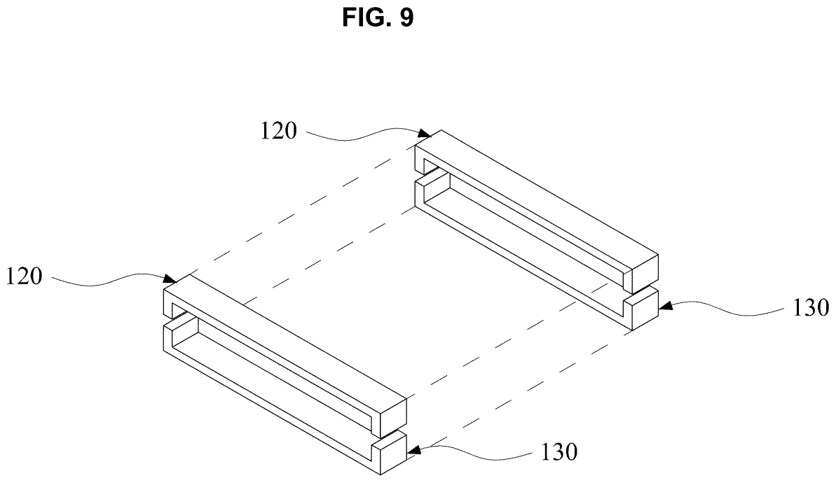

Meanwhile, FIG. 8 is a front view of a semiconductor module including a heat radiation system according to a second embodiment of the present invention and FIG. 9 illustrates the semiconductor module including a heat radiation system of FIG. 8 where an upper cover and a lower cover are separated from each other. Referring to FIGS. 8 and 9, the non-conductive first upper heat radiation component 120 and first lower heat radiation component 130 face and cover the semiconductor component 110. Also, the second upper heat radiation component 140 covers the first upper heat radiation component 120 and the second lower heat radiation component 150 covers the first lower heat radiation component 130. In this regard, the first upper heat radiation component 120 and the first lower heat radiation component 130 may cover the semiconductor component 110 with a minimum area to maximize heat radiation efficiency and may prevent a short circuit between the terminals 117 and the heat radiation system.

That is, referring to FIG. 9, the first upper heat radiation component 120 and the first lower heat radiation component 130 may each be separated and disposed on both openings A where the terminals 117 extended toward the outside of the molding housing of the semiconductor component 110 are formed. Accordingly, only a minimum area which is adjacent to the terminals 117 is insulated with a non-conductive material so as to maximize heat radiation efficiency. Also, a short between the terminals 117 and a heat radiation system in an area adjacent to the terminals 117 may be blocked to secure insulation reliability between the semiconductor component 110 and the heat radiation system.

According to the semiconductor module including a heat radiation system described above, non-conductive and conductive heat radiation components cover semiconductor components in four or more stages so that heat radiation efficiency of the heat radiation system may be maintained and an insulation distance between high density and high power semiconductor components and terminals may be secured. In this regard, a short-circuit occurring due to unexpected air insulation breakdown between the terminals and the heat radiation system may be blocked and thereby, insulation reliability between the semiconductor components and the heat radiation system may be secured.

According to the present invention, non-conductive and conductive heat radiation components cover semiconductor components in four or more stages so that heat radiation efficiency of the heat radiation system may be maintained and an insulation distance between high density and high power semiconductor components and terminals may be secured. In this regard, a short-circuit occurring due to unexpected air insulation breakdown between the terminals and the heat radiation system may be blocked and thereby, insulation reliability between the semiconductor components and the heat radiation system may be secured.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor module comprising a heat radiation system comprising:
at least one semiconductor component comprising at least one terminal extended toward the outside and electrically connected to other components;
a first upper heat radiation component combined to the upper part of the semiconductor component;
a first lower heat radiation component combined to the lower part of the semiconductor component to face the first upper heat radiation component;
a second upper heat radiation component joined to the upper part of the first upper heat radiation component; and
a second lower heat radiation component joined to the lower part of the first lower heat radiation component,
wherein a coolant used to cool heat generated from the semiconductor component circulates between the first and second upper heat radiation components or between the first and second lower heat radiation components, the second upper heat radiation component or the second lower heat radiation component comprises at least one hole through which a coolant flows in and discharges, and at least any one of the first upper heat radiation component, the first lower heat radiation component, the second upper heat radiation component, and the second lower heat radiation component is formed of a material that is different from each other.

2. The semiconductor module comprising a heat radiation system of claim 1, wherein the first upper heat radiation component and the second upper heat radiation component are formed of each different material or the first lower heat radiation component and the second lower heat radiation component are formed of each different material.

3. The semiconductor module comprising a heat radiation system of claim 1, wherein the first upper heat radiation component and the first lower heat radiation component are formed of a non-conductive material and the second upper heat radiation component and the second lower heat radiation component are formed of a conductive material.

4. The semiconductor module comprising a heat radiation system of claim 2, wherein the semiconductor component comprises an insulating substrate, at least one semiconductor chip installed on the insulating substrate, a molding housing covering the semiconductor chips, and terminals extended toward the outside of the molding housing, wherein the insulating substrate partially or entirely has a dual side cooling structure which is exposed from the molding housing.

5. The semiconductor module comprising a heat radiation system of claim 3, wherein the semiconductor component comprises an insulating substrate, at least one semiconductor chip installed on the insulating substrate, a molding housing covering the semiconductor chips, and terminals extended toward the outside of the molding housing, wherein the insulating substrate partially or entirely has a dual side cooling structure which is exposed from the molding housing.

6. The semiconductor module comprising a heat radiation system of claim 1, wherein upper radiation components comprising the first upper heat radiation component and the second upper heat radiation component and lower radiation components comprising the first lower heat radiation component and the second lower heat radiation component are assembled to each other by using assembling parts, screwing, an adhesive, laser welding or ultrasonic welding.

7. The semiconductor module comprising a heat radiation system of claim 1, wherein upper joining means are interposed between the first upper heat radiation component and the upper surface of the semiconductor component and lower joining means are interposed between the first lower heat radiation component and the lower surface of the semiconductor component.

8. The semiconductor module comprising a heat radiation system of claim 7, wherein the upper joining means or the lower joining means are O-rings which are formed of an elastic material.

9. The semiconductor module comprising a heat radiation system of claim 7, wherein the upper joining means or the lower joining means are paste-form adhesives which are hardened at a predetermined temperature so that the semiconductor component, the first upper heat radiation component, and the first lower heat radiation component are bonded to each other.

10. The semiconductor module comprising a heat radiation system of claim 1, wherein a plurality of radiation fins arranged in a specific pattern is uprightly formed on at least any one of the upper surface and the lower surface of the semiconductor component.

11. The semiconductor module comprising a heat radiation system of claim 1, wherein the first upper heat radiation component or the first lower heat radiation component is formed of an insulating material.

12. The semiconductor module comprising a heat radiation system of claim 1, wherein the weight of the first upper heat radiation component or the first lower heat radiation component is less than the weight of the second upper heat radiation component or the second lower heat radiation component.

13. The semiconductor module comprising a heat radiation system of claim 1, wherein first concave parts are formed on the upper part of the first upper heat radiation component and first convex parts corresponding to the first concave parts are formed on the lower part of the second upper heat radiation component so as to be joined to each other, and second concave parts are formed on the lower part of the first lower heat radiation component and second convex parts corresponding to the second concave parts are formed on the upper part of the second lower heat radiation component so as to be joined to each other.

14. The semiconductor module comprising a heat radiation system of claim 1, wherein first concave parts are formed on the upper part of the first upper heat radiation component, first O-rings are entered into the first concave parts, second concave parts are formed on the lower part of the first lower heat radiation component, and second O-rings are entered into the second concave parts.

15. The semiconductor module comprising a heat radiation system of claim 1, wherein first concave parts are formed on the upper part of the first upper heat radiation component, first adhesives are filled in the first concave parts, second concave parts are formed on the lower part of the first lower heat radiation component, and second adhesives are filled in the second concave parts.

16. The semiconductor module comprising a heat radiation system of claim 1, wherein first hooks are formed along the upper edge of the first upper heat radiation component, first hook holes corresponding to the first hooks are formed on the lower part of the second upper heat radiation component, second hooks are formed along the lower edge of the first lower heat radiation component, and second hook holes corresponding to the second hooks are formed on the upper part of the second lower heat radiation component.

17. The semiconductor module comprising a heat radiation system of claim 16, wherein the size of the first hook holes and second hook holes is respectively larger than the size of the first hooks and second hooks and O-rings are each buried and installed to the first hook holes and the second hook holes.

18. The semiconductor module comprising a heat radiation system of claim 17, wherein a connection structure of the first hook holes and the first hooks and a connection structure of the second hook holes and the second hooks are a cylindrical form, a hexahedral form, or an interlocked structure having a specific form.

19. The semiconductor module comprising a heat radiation system of claim 1, wherein the first upper heat radiation component and the first lower heat radiation component face and cover the semiconductor component, the second upper heat radiation component covers the first upper heat radiation component, and the second lower heat radiation component covers the first lower heat radiation component.

20. The semiconductor module comprising a heat radiation system of claim 19, wherein the first upper heat radiation component and the first lower heat radiation component are each separated and disposed on both openings where the terminals extended toward the outside of the molding housing of the semiconductor component are formed.
